(19) United States
(12) Patent Application Publication
(10) Pub. No.: US 2019/0035660 A1
(43) Pub. Date: Jan. 31, 2019

(54) PURGING DEVICE AND METHOD FOR PURGING A DELIVERING CONTAINER ON A LOAD PORT

(71) Applicant: SPRINGFIELD TECHNOLOGIES & INTELLIGENCE, INC., Taipei City (TW)

(72) Inventors: Kuan-Ting LIN, Taipei City (TW); Wang-Chang WANG, Taipei City (TW)

(21) Appl. No.: 15/997,011

(22) Filed: Jun. 4, 2018

(30) Foreign Application Priority Data
Jul. 25, 2017 (TW) 106124816

(51) Int. Cl. H01L 21/673; H01L 21/677; H01L 21/67

(52) U.S. Cl. CPC H01L 21/67393; H01L 21/67017; H01L 21/67769

(57) ABSTRACT

A purging device includes an intake module, an exhausting module, a first purge gas supplying module, a second purge gas supplying module, a control valve and a processing module. The processing module is electrically connected to the control valve, and is operable so as to control the control valve to allow flow of a first purge gas from the first purge gas supplying module into the intake module, while preventing flow of a second purge gas from the second purge gas supplying module into the intake module, or allow flow of the second purge gas from the second purge gas supplying module into the intake module, while preventing flow of the first purge gas from the first purge gas supplying module into the intake module.

### CROSS-REFERENCE TO RELATED APPLICATION

This application claims priority of Taiwanese Patent Application No. 106124816, filed on Jul. 25, 2017.

### FIELD

The disclosure relates to a load port, and more particularly to a purging device of the load port that is disposed for semiconductor manufacturing process, and that can selectively provide different purge gases for purging a delivering container.

### BACKGROUND

A conventional load port is mounted to one side of a semiconductor manufacturing device, and is disposed for carrying a front opening unified pod (FOUP) such that, wafers stored in the FOUP can be picked by the semiconductor manufacturing device through operation of the conventional load port.

Since a purging device of the conventional load port can provide only one kind of purging gas for purging an interior of the FOUP. Therefore, the conventional load port can only cooperate with the FOUP in a specific manufacturing process, and the applicable range of the conventional load port is limited.

### SUMMARY

Therefore, an object of the disclosure is to provide a purging device for a load port that can selectively provide different purge gases according to the requirements of a user so as to increase the flexible usage.

According to the disclosure, the purging device includes an intake module, an exhausting module, a first purge gas supplying module, a second purge gas supplying module, a control valve and a processing module. The exhausting module is connected to the intake module. The first purge gas supplying module is adapted for supplying a first purge gas to the intake module. The second purge gas supplying module is adapted for supplying a second purge gas that is different from the first purge gas to the intake module. The control valve is connected among the first and second purge gas supplying modules and the intake module. The processing module is electrically connected to the control valve, and is operable so as to control the control valve to allow flow of the first purge gas from the first purge gas supplying module into the intake module, while preventing flow of the second purge gas from the second purge gas supplying module into the intake module, or allow flow of the second purge gas from the second purge gas supplying module into the intake module, while preventing flow of the first purge gas from the first purge gas supplying module into the intake module.

Therefore, another object of the disclosure is to provide a method for purging a delivering container.

According to the disclosure, the method is adapted for purging a delivering container during movement of the delivering container between a loading position, where the delivering container is spaced apart from a movable door of a load port, and an unloading position, where a front door of the delivering door is connected co-movably to the movable door, and where the movable door is moved vertically between an upper position and a lower position. At the upper position, the front door of the delivering container is closed, and when the movable door is moved from the upper position to the lower position, the front door of the delivering container is carried by the movable door to move to an open position. The delivering container is detachably mountable to a carrier plate of the load port. The movement includes a first period during which the delivering container is moved from the loading position to the unloading position when the movable door is at the upper position, a second period during which the movable door is moved from the upper position to the lower position, and is subsequently returned from the lower position to the upper position, and a third period during which the delivering container is moved from the unloading position to the loading position such that the front door of the delivering container is disconnected from the movable door. The method includes an initial purging step, a main purging step and a final purging step. The initial purging step is performed during the first period of the movement. In the initial purging step, the delivering container is carried by the carrier plate to move from the loading position to the unloading position to thereby connect the front door of the delivering container to the movable door of the load port, a processing module is operated to perform a first purging process, in which the processing module operates a control valve to allow flow of a first purge gas from a first purge gas supplying module into the delivering container through an intake module that extends through the carrier plate, while preventing flow of a second purge gas from a second purge gas supplying module into the delivering container, and the first purge gas in the delivering container is dischargeable through an exhausting module that extends through the carrier plate. The main purging step is performed during the second period of the movement. In the main purging step, when the front door is moved from the upper position to the lower position, the processing module is operated to selectively perform one of the first purging process and a second purging process in which the processing module operates the control valve to allow flow of the second purge gas from the second purge gas supplying module into the delivering container through the intake module, while preventing flow of the first purge gas from the first purge gas supplying module into the delivering container, and the gas in the delivering container is dischargeable through the exhausting module. The final purging step is performed during the third period of the movement. In the final purging step, the processing module is operated to perform the second purging process.

### BRIEF DESCRIPTION OF THE DRAWINGS

Other features and advantages of the disclosure will become apparent in the following detailed description of the embodiment with reference to the accompanying drawings, of which:

FIG. 1 is a perspective view of an embodiment of a purging device according to the disclosure, which is mounted to a load port;

FIG. 2 is a top view of a carrier plate of the load port;

FIG. 3 is a bottom view of the carrier plate, and illustrates that an intake module and an exhausting module of the embodiment are mounted to a bottom side of the carrier plate;

FIG. 4 is a block diagram of the embodiment;

FIG. 5 is a flow diagram of a purging method of the embodiment;

FIG. 6 is a schematic view of the embodiment, illustrating the start timing and the stop timing of an initial purging step of the purging method;

FIG. 7 is a view similar to FIG. 6, but illustrating the start timing and the stop timing of a main purging step of the purging method; and

FIG. 8 is a view similar to FIG. 6, but illustrating the start timing and the stop timing of a final purging step of the purging method.

### DETAILED DESCRIPTION

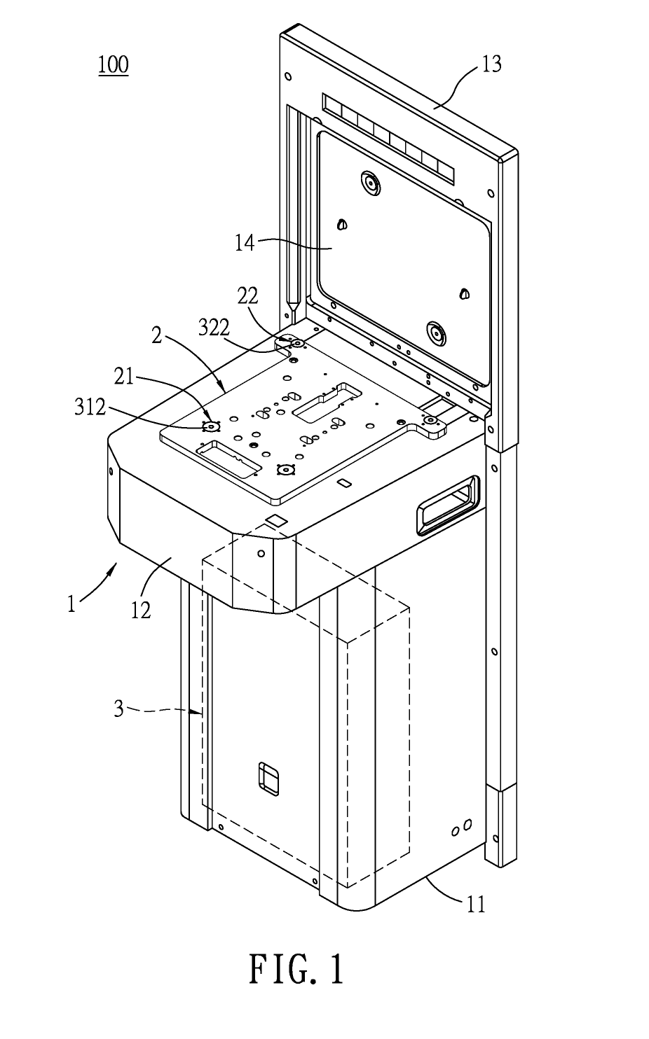

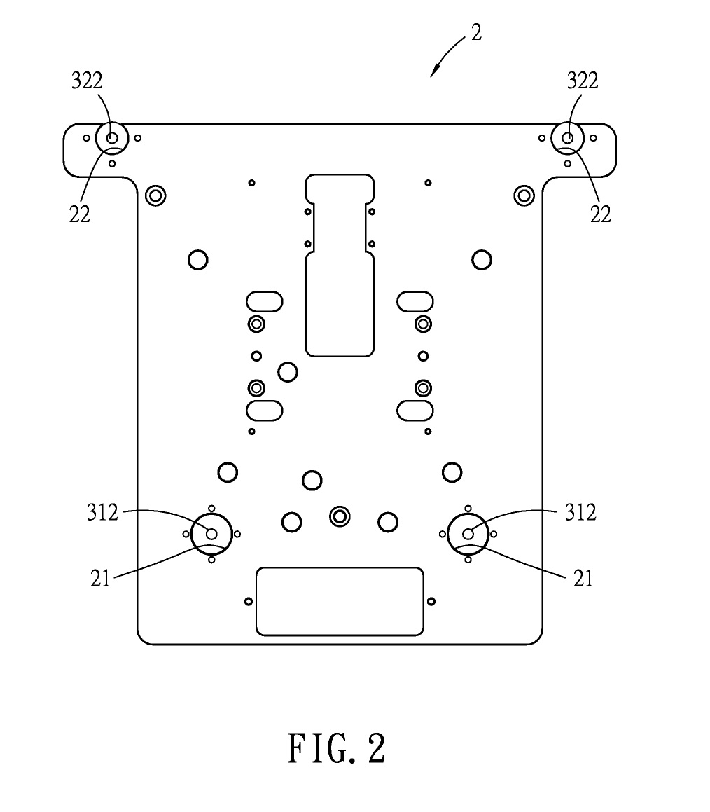

Referring to FIGS. 1 and 2, the embodiment of a purging device according to the disclosure is adapted for use in a load port 100, and is adapted for purging a delivering container 6 (see FIG. 6) which is detachably disposed on the load port 100. The load port 100 is disposed at one side of a semiconductor manufacturing device (not shown). The delivering container 6 is disposed for receiving wafers or masks.

It should be noted that, in this embodiment, the delivering container 6 is a front opening unified pod (FOUP) disposed for receiving the wafers, and the configuration of the delivering container 6 may be varied in other embodiments.

The load port 100 includes a machine seat 1, a carrier plate 2 and a purging device 3. The machine seat 1 includes a seat body 11, a platform 12 mounted on a top end of the seat body 11, a frame 13 mounted to the seat body 11 and the platform 12, and a movable door 14 movably mounted to the frame 13. The carrier plate 2 is disposed on the platform 12 for carrying the delivering container 6 so as to allow a front door 61 (see FIG. 6) of the delivering container 6 to move toward and away from the movable door 14. With such disposition, the semiconductor manufacturing device can pick the wafers from the delivering container 6 when the front door 61 of the delivering container 6 and the movable door 14 of the machine seat 1 are opened. The carrier plate 2 is formed with two first mounting holes 21 located at an end portion thereof distal from the movable door 14, and spaced apart from each other in a right-left direction, and two second mounting holes 22 located proximate to the movable door 14, and spaced apart from each other in the right-left direction.

The delivering container 6 is movable between a loading position, where the delivering container 6 is spaced apart from the movable door 14, and an unloading position, where the front door 61 of the delivering door 6 is connected co-movably to the movable door 14, and where the movable door 14 is moved vertically between an upper position and a lower position such that, when at the upper position, the front door 61 of the delivering container 6 is closed, and when the movable door 14 is moved from the upper position to the lower position, the front door 61 of the delivering container 6 is carried by the movable door 14 to move to an open position. The movement of the delivering container 6 includes a first period during which the delivering container 6 is moved from the loading position to the unloading position when the movable door 14 is at the upper position, a second period during which the movable door 14 is moved from the upper position to the lower position, and is subsequently returned from the lower position to the upper position, and a third period during which the delivering container 6 is moved from the unloading position to the loading position such that the front door 61 of the delivering container 6 is disconnected from the movable door 14.

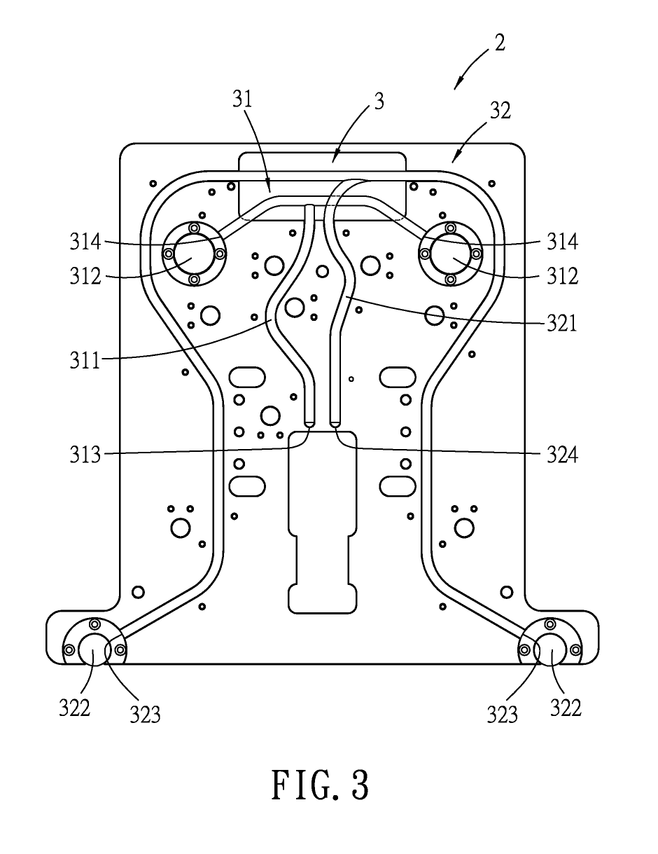

Referring to FIGS. 2 and 3, the purging device 3 includes an intake module 31 connected to the delivering container 6, and an exhausting module 32 connected to the intake module 31 and the delivering container 6. The intake module 31 includes an intake tube 311 and two intake nozzles 312. The intake tube 311 is adapted to be embedded to a bottom portion of the carrier plate 2, and has a gas inlet opening 313, and two intake openings 314. The intake nozzles 312 are respectively mounted in the first mounting holes 21, and are respectively communicated with the intake openings 314 of the intake tube 311. Each of the intake nozzles 312 is adapted to be connected to a corresponding one of gas inlet valves (not shown) of the delivering container 6. The exhausting module 32 includes an exhausting tube 321 and two exhausting nozzles 322. The exhausting tube 321 is adapted to be embedded to the bottom portion of the carrier plate 2, and has two gas outlet openings 323 and an exhausting opening 324. The exhausting nozzles 322 are respectively mounted in the second mounting holes 22, and are respectively communicated with the gas outlet openings 323 of the exhausting tube 321. Each of the exhausting nozzles 322 is adapted to be connected to a corresponding one of gas outlet valves (not shown) of the delivering container 6.

Referring to FIGS. 1, 4 and 6, the purging device 3 further includes a first purge gas supplying module 33, a second purge gas supplying module 34, a control valve 35, a flow controller 36, a filter 37, a processing module 38, a sensing module 39, an exhausting valve 40, an exhaust gas pressure regulator 41 and an exhaust gas treatment module 42. The first purge gas supplying module 33, the second purge gas supplying module 34, the control valve 35, the flow controller 36, the filter 37, the processing module 38, the sensing module 39, the exhausting valve 40, the exhaust gas pressure regulator 41, and the exhaust gas treatment module 42 are mounted in the seat body 11.

The first purge gas supplying module 33 includes a first purge gas supplier 331 adapted for providing a first purge gas to the intake module 31, and a first purge gas pressure regulator 332 connected between the first purge gas supplier 331 and the control valve 35. It should be noted that, in this embodiment, the first purge gas is clean dry air (CDA) or extreme clean dry air (XCDA), and the first purge gas may be changed to other gases in other embodiments. The first purge gas pressure regulator 332 is electrically connected to the processing module 38, and is adapted for measuring and regulating the pressure of the first purge gas passing through the first purge gas pressure regulator 332. In this embodiment, the first purge gas pressure regulator 332 includes a first pressure sensor 333 and a first pressure regulating valve 334. The first pressure sensor 333 is adapted for measuring the pressure of the first purge gas, and transfers the pressure value to a first pressure sensing signal. The first pressure regulating valve 334 is adapted for regulating the pressure of the first purge gas. When receiving the first pressure sensing signal, the processing module 38 determines whether the pressure value of the first purge gas corresponds to a preset pressure value. When the pressure value of the first purge gas does not correspond to the preset pressure value, the processing module 38 drives the first pressure regulating valve 334 to regulate the pressure value of the first purge gas to correspond with the preset pressure value.

The second purge gas supplying module 34 includes a second purge gas supplier 341 adapted for providing a second purge gas that is different from the first purge gas to the intake module 31, and a second purge gas pressure regulator 342 connected between the second purge gas supplier 341 and the control valve 35. It should be noted that, in this embodiment, the second purge gas is nitrogen gas, and the second purge gas may be changed to other gases in other embodiments. The second purge gas pressure regulator 342 is electrically connected to the processing module 38, and is adapted for measuring and regulating the pressure of the second purge gas passing through the second purge gas pressure regulator 342. In this embodiment, the second purge gas pressure regulator 342 includes a second pressure sensor 343 and a second pressure regulating valve 344. The second pressure sensor 343 is adapted for measuring the pressure of the second purge gas, and transfers the pressure value to a second pressure sensing signal. The second pressure regulating valve 344 is adapted for regulating the pressure of the second purge gas. When receiving the second pressure sensing signal, the processing module 38 determines whether the pressure value of the second purge gas corresponds to a preset pressure value. When the pressure value of the second purge gas does not correspond to the preset pressure value, the processing module 38 drives the second pressure regulating valve 344 to regulate the pressure value of the second purge gas to correspond with the preset pressure value.

In this embodiment, the control valve 35 is a switching solenoid, and is connected among the first purge gas pressure regulator 332 of the first purge gas supplying module 33, the second purge gas pressure regulator 342 of the second purge gas supplying modules 34 and the gas inlet opening 313 of the intake module 31. The control valve 35 is disposed for controlling flow of the first purge gas supplying module 33 and flow of the second purge gas supplying module 34.

The processing module 38 is electrically connected to the control valve 35, and is operable so as to control the control valve 35 to allow flow of the first purge gas from the first purge gas supplying module 33 into the intake module 31, while preventing flow of the second purge gas from the second purge gas supplying module 34 into the intake module 31, or allow flow of the second purge gas from the second purge gas supplying module 34 into the intake module 31, while preventing flow of the first purge gas from the first purge gas supplying module 33 into the intake module 31. In detail, the processing module 38 is electrically connected to a manufacturing execute system (MES) 5 such that, the MES 5 controls the processing module 38 to control the control valve 35. When the processing module 38 is operated to control the control valve 35 to allow passage of the first purge gas and prevent passage of the second purge gas, the first purge gas enters the delivering container 6 through the intake module 31 and exits the delivering container 6 through the exhausting module 32. When the processing module 38 is operated to control the control valve 35 to allow passage of the second purge gas and prevent passage of the first purge gas, the second purge gas enters the delivering container 6 through the intake module 31 and exits the delivering container 6 through the exhausting module 32.

The flow controller 36 is disposed between the control valve 35 and the gas inlet opening 313 of the intake module 31, and is electrically connected to the processing module 38. The processing module 38 drives the flow controller 36 to control the flow rate of the first purge gas and the second purge gas in the gas inlet opening 313 of the intake module 31.

The filter 37 is disposed between the flow controller 36 and the gas inlet opening 313 of the intake module 31 for filtering and purifying the first purge gas and the second purge gas.

The sensing module 39, the exhausting valve 40 and the exhaust gas pressure regulator 41 are disposed at an exhausting pipe (not shown). The exhausting pipe is mounted in the seat body 11, and is communicated with the exhausting opening 324 of the exhausting module 32. The sensing module 39 is connected to the exhausting module 32, and is electrically connected to the processing module 38 for measuring physical parameters of an exhaust gas discharged through the exhausting opening 324 of the exhausting module 32 (see FIG. 3) The sensing module 39 includes a humidity sensor 391 adapted for measuring the humidity of the exhaust gas, a temperature sensor 392 adapted for measuring the temperature of the exhaust gas, and an oxygen sensor 393 adapted for measuring the oxygen concentration of the exhaust gas.

The exhausting valve 40 is electrically connected to the processing module 38 such that, the processing module 38 drives the exhausting valve 40 to discharge the exhaust gas from the exhausting pipe.

The exhaust gas pressure regulator 41 is electrically connected to the processing module 38, is connected to the sensing module 39, and is adapted for measuring and regulating the pressure of the exhaust gas. In this embodiment, the exhaust gas pressure regulator 41 includes a third pressure sensor 411 adapted for measuring the pressure of the exhaust gas and transferring the pressure value to a third pressure sensing signal, and a third pressure regulating valve 412 adapted for regulating the pressure of the exhaust gas. When receiving the third pressure sensing signal, the processing module 38 determines whether the pressure value of the exhaust gas corresponds to a preset pressure value. When the pressure value of the exhaust gas does not correspond to the preset pressure value, the processing module 38 then drives the third pressure regulating valve 412 to regulate the pressure value of the exhaust gas to correspond with the preset pressure value.

The exhaust gas treatment module 42 is connected to one end of the exhausting pipe that is opposite to the exhausting opening 324 of the exhausting module 32, and is adapted for treating and removing contaminants in the exhaust gas which is discharged by the exhausting module 32, the sensing module 39 and the exhaust gas pressure regulator 41. With such disposition, the exhaust gas won't contaminate the outer environment.

Referring to FIGS. 1, 3, 4 and 6, during operation, the MES 5 firstly controls the processing module 38 to allow the passage of the first purge gas or the passage of the second purge gas. It should be noted that, since the operation won't be different with different purge gases, the following operation will be described under the condition that the processing module 38 allows the passage of the first purge gas for sake of brevity. The processing module 38 drives the control valve 35 to allow the passage of the first purge gas and prevent the passage of the second purge gas. In such manner, the first purge gas enters the gas inlet opening 313 of the intake module 31. Before the first purge gas enters the gas inlet opening 313, the flow controller 36 controls the flow rate of the first purge gas, and the filter 37 filters and purifies the first purge gas to maintain the cleanness of the first purge gas.

After entering the gas inlet opening 313, the first purge gas sequentially passes through the intake tube 311, the intake nozzles 312 and the gas inlet vales of the delivering container 6 to enter the delivering container 6. Subsequently, the first purge gas drives mist and oxygen which are retained in the delivering container 6 to sequentially move past the gas outlet valves of the delivering container 6, the exhausting nozzles 322 and the exhausting tube 321, and is then discharged from the exhausting opening 324. In such manner, the mist and the oxygen which are retained in the delivering container 6 can be removed for preventing the wafers from damage.

Afterward, the exhaust gas discharged from the exhausting opening 324 flows through the sensing module 39, and the humidity sensor 391, the temperature sensor 392 and the oxygen sensor 393 of the sensing module 39 respectively measure the humidity, the temperature and the oxygen concentration of the exhaust gas. When the sensing module 39 measures the humidity, the temperature and the oxygen concentration of the exhaust gas, it transfers the measured values to sensing signals, and sends the sensing signals to the processing module 38. The processing module 38 then transfers the sensing signals to digital signals and stores the digital signals. Subsequently, the processing module 38 determines the values of the humidity, the temperature and the oxygen concentration of the exhaust gas with built-in programs and algorithms. When any one of values of the humidity, the temperature and the oxygen concentration of the exhaust gas is over a standard value, the processing module 38 sends a signal to MES 5 to carry out necessary steps. Therefore, the cleanness of the interior of the delivering container 6 can be controlled appropriately. Finally, the exhaust gas sequentially flows through the exhausting valve 40, the exhaust gas pressure regulator 41 and the exhaust gas treatment module 42 and into the outer environment.

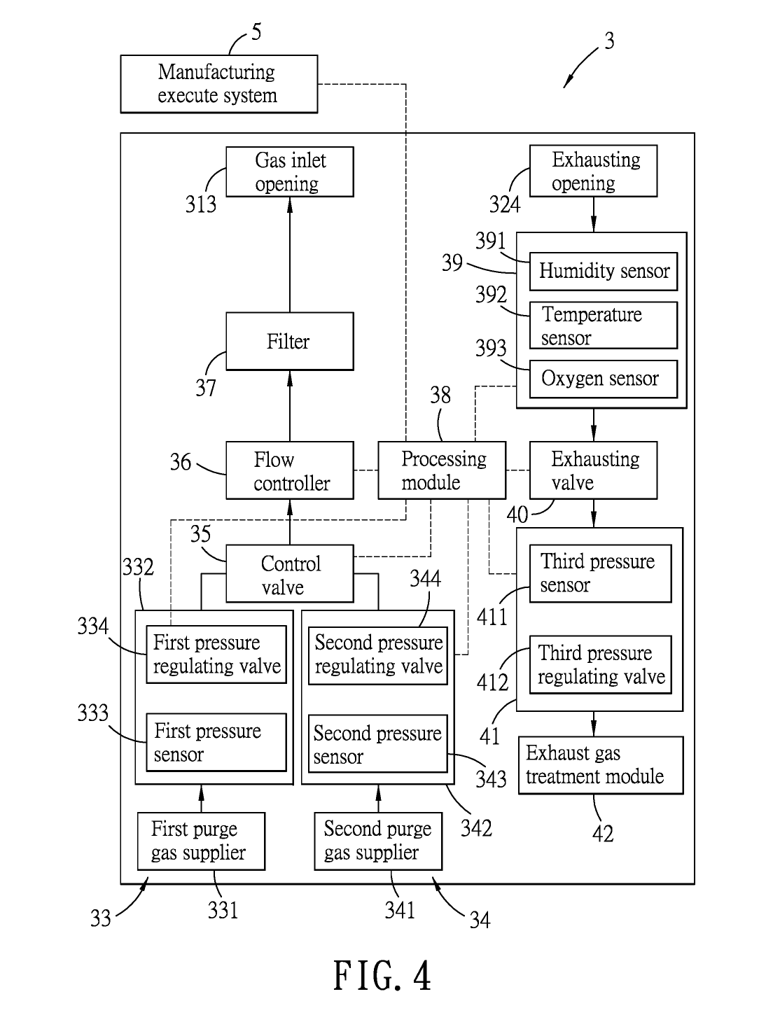

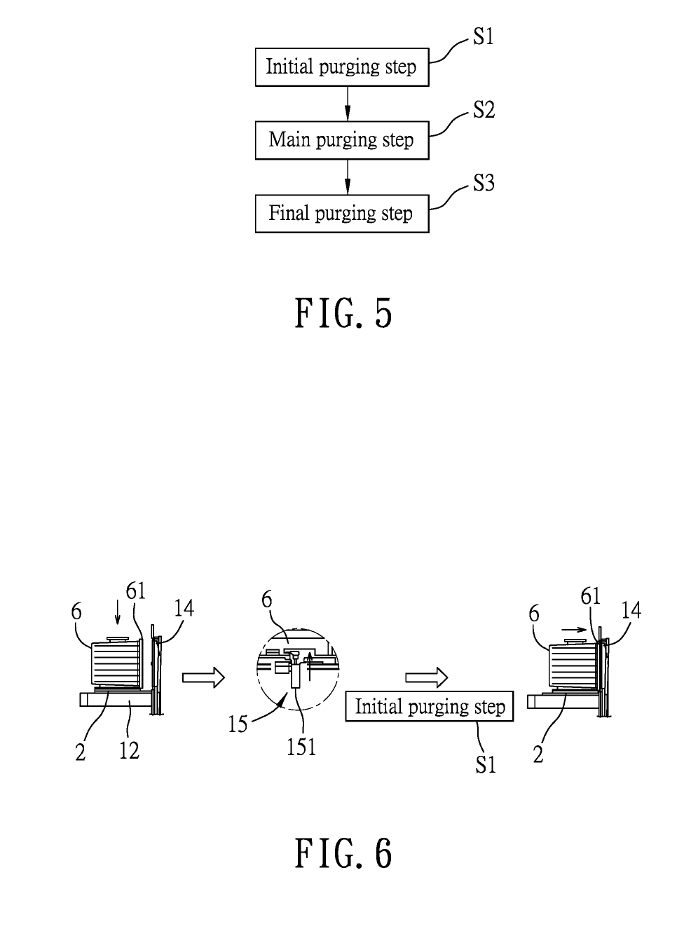

Referring to FIGS. 4 to 6, the method adapted for purging the delivering container 6 includes an initial purging step (S1), a main purging step (S2) and a final purging step (S3).

In the initial purging step (S1), when the delivering container 6 is fixed to the carrier plate 2 by a fixing mechanism 15, the processing module 38 is operated to perform a first purging process, and, when the front door 61 of the delivering container 6 is connected to the movable door 14 of the load port 100, the first purging process stops.

In detail, the initial purging step (S1) is performed during the first period of the movement, where the delivering container 6 is carried by the carrier plate 2 to move from the loading position to the unloading position to thereby connect the front door 61 of the delivering container 6 with the movable door 14 of the load port 100. When the delivering container 6 is fixed to the carrier plate 2 by a plurality of fixing members 151 of the fixing mechanism 15, the processing module 38 is operated to perform the first purging process, in which the processing module 38 operates the control valve 35 to allow the flow of the first purge gas from the first purge gas supplying module 33 into the delivering container 6 through the intake module 31, while preventing the flow of the second purge gas from the second purge gas supplying module 34 into the delivering container 6, and the first purge gas in the delivering container 6 is dischargeable through the exhausting module 32.

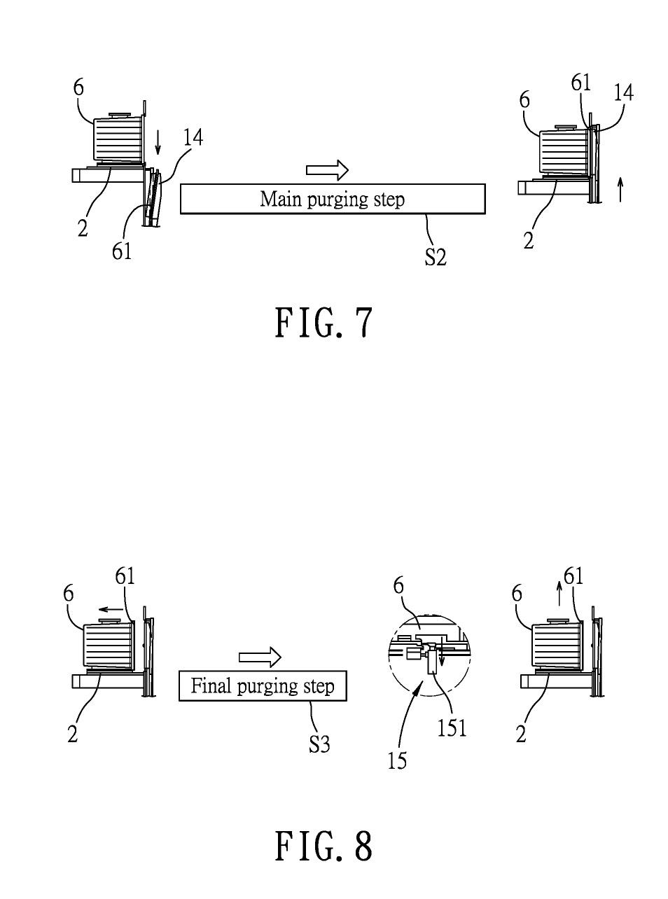

Referring to FIGS. 4, 5 and 7, in the main purging step (S2), when the front door 61 of the delivering container 6 is moved downwardly with the movable door 14, the processing module 38 is operated to perform a selected one of the first purging process and a second purging process, and, when the front door 61 is moved upwardly with the movable door 14, the selected one of the first purging process and the second purging process stops.

In detail, the main purging step (S2) is performed during the second period of the movement, where the front door 61 is moved from the upper position to the lower position. The processing module 38 is operated to selectively perform one of the first purging process and the second purging process, in which the processing module 38 operates the control valve 35 to allow the flow of the second purge gas from the second purge gas supplying module 34 into the delivering container 6 through the intake module 31, while preventing the flow of the first purge gas from the first purge gas supplying module 33 into the delivering container 6, and the gas in the delivering container 6 is dischargeable through the exhausting module 32.

Referring to FIGS. 4, 5 and 8, in the final purging step (S3), when the front door 61 is disconnected from the movable door 14, the processing module 38 is operated to perform the second purging process, and, when the fixing mechanism 15 is operated to release the delivering container 6 from the carrier plate 2, the second purging process stops.

In detail, the final purging step (S3) is performed during the third period of the movement, the delivering container 6 is carried by the carrier plate 2 to move from the unloading position to the loading position. When the delivering container 6 leaves from the loading position, the processing module 38 is operated to perform the second purging process. As such, the second purging process in the final purging step (S3) can be assured to be performed under the condition that the front door 61 of the delivering container 6 is completely closed, so that gas in the outer environment cannot flow into the delivering container 6. In such manner, the values of the humidity of the interior of the delivering container 6 and the quantity of micro-polluted particles produced during the manufacturing process can be decreased to standard values.

In conclusion, in the purging device 3, the processing module 38 can be operated to perform a selected one of the first purging process and the second purging process based on the requirement of a user so as to provide different purge gases to clean the interior of the delivering container 6 in different manufacturing processes. Therefore, the flexible usage can be increased.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A purging device adapted for use in a load port, and comprising:
an intake module;
an exhausting module connected to said intake module;
a first purge gas supplying module adapted for supplying a first purge gas to said intake module;
a second purge gas supplying module adapted for supplying a second purge gas that is different from the first purge gas to said intake module;
a control valve connected among said first and second purge gas supplying modules and said intake module; and
a processing module electrically connected to said control valve,
wherein said processing module is operable so as to control said control valve to
allow flow of the first purge gas from said first purge gas supplying module into said intake module, while preventing flow of the second purge gas from said second purge gas supplying module into said intake module, or
allow flow of the second purge gas from said second purge gas supplying module into said intake module, while preventing flow of the first purge gas from said first purge gas supplying module into said intake module.

2. The purging device as claimed in claim 1, wherein:
said first purge gas supplying module includes
a first purge gas supplier adapted for providing the first purge gas, and
a first purge gas pressure regulator connected between said first purge gas supplier and said control valve, being electrically connected to said processing module, and being adapted for measuring and regulating the pressure of the first purge gas passing through said first purge gas pressure regulator; and
said second purge gas supplying module includes
a second purge gas supplier adapted for providing the second purge gas, and
a second purge gas pressure regulator connected between said second purge gas supplier and said control valve, being electrically connected to said processing module, and being adapted for measuring and regulating the pressure of the second purge gas passing through said second purge gas pressure regulator.

3. The purging device as claimed in claim 2, wherein:
said first purge gas pressure regulator includes
a first pressure sensor adapted for measuring the pressure of the first purge gas, and
a first pressure regulating valve adapted for regulating the pressure of the first purge gas; and
said second purge gas pressure regulator includes
a second pressure sensor adapted for measuring the pressure of the second purge gas, and
a second pressure regulating valve adapted for regulating the pressure of the second purge gas.

4. The purging device as claimed in claim 1, further comprising a sensing module that is electrically connected to said processing module, that is connected to said exhausting module, and that includes a humidity sensor adapted for measuring the humidity of an exhaust gas discharged by said exhausting module, a temperature sensor adapted for measuring the temperature of the exhaust gas, and an oxygen sensor adapted for measuring the oxygen concentration of the exhaust gas.

5. The purging device as claimed in claim 4, further comprising an exhaust gas pressure regulator that is electrically connected to said processing module, that is connected to said sensing module, and that is adapted for measuring and regulating the pressure of the exhaust gas.

6. The purging device as claimed in claim 5, wherein said exhaust gas pressure regulator includes a third pressure sensor adapted for measuring the pressure of the exhaust gas, and a third pressure regulating valve adapted for regulating the pressure of the exhaust gas.

7. The purging device as claimed in claim 5, further comprising an exhaust gas treatment module that is connected to said exhaust gas pressure regulator and that is adapted for treating and removing contaminants in the exhaust gas.

4. purging device as claimed in claim 4, further comprising an exhaust gas treatment module that is connected to said sensing module and that is adapted for treating and removing contaminants in the exhaust gas.

9. The purging device as claimed in claim 1, further comprising an exhaust gas treatment module that is connected to said exhausting module and that is adapted for treating and removing contaminants in an exhaust gas discharged by said exhausting module.

10. The purging device as claimed in claim 1, wherein:
said purging device is adapted for purging a delivering container that is detachably disposed on the load port;
said intake module and said exhausting module are connected to the delivering container;
when said processing module is operated to control said control valve to allow passage of the first purge gas and prevent passage of the second purge gas, the first purge gas enters the delivering container through said intake module and exits the delivering container through said exhausting module; and
when said processing module is operated to control said control valve to allow passage of the second purge gas and prevent passage of the first purge gas, the second purge gas enters the delivering container through said intake module and exits the delivering container through said exhausting module.

11. A method adapted for purging a delivering container during movement of the delivering container between a loading position, where the delivering container is spaced apart from a movable door of a load port, and an unloading position, where a front door of the delivering door is connected co-movably to the movable door, and where the movable door is moved vertically between an upper position and a lower position such that, when at the upper position, the front door of the delivering container is closed, and when the movable door is moved from the upper position to the lower position, the front door of the delivering container is carried by the movable door to move to an open position, the delivering container being detachably mountable to a carrier plate of the load port, the movement including a first period during which the delivering container is moved from the loading position to the unloading position when the movable door is at the upper position, a second period during which the movable door is moved from the upper position to the lower position, and is subsequently returned from the lower position to the upper position, and a third period during which the delivering container is moved from the unloading position to the loading position such that the front door of the delivering container is disconnected from the movable door, the method comprising:
an initial purging step performed during the first period of the movement, wherein the delivering container is carried by the carrier plate to move from the loading position to the unloading position to thereby connect the front door of the delivering container to the movable door of the load port, a processing module is operated to perform a first purging process, in which the processing module operates a control valve to allow flow of a first purge gas from a first purge gas supplying module into the delivering container through an intake module that extends through the carrier plate, while preventing flow of a second purge gas from a second purge gas supplying module into the delivering container, and the first purge gas in the delivering container is dischargeable through an exhausting module that extends through the carrier plate;
a main purging step performed during the second period of the movement, wherein, when the front door is moved from the upper position to the lower position, the processing module is operated to selectively perform one of the first purging process and a second purging process in which the processing module operates the control valve to allow flow of the second purge gas from the second purge gas supplying module into the delivering container through the intake module, while preventing flow of the first purge gas from the first purge gas supplying module into the delivering container, and the gas in the delivering container is dischargeable through the exhausting module; and
a final purging step performed during the third period of the movement, wherein the processing module is operated to perform the second purging process.

12. The method as claimed in claim 11, wherein, in the initial purging step, when the delivering container is fixed to the carrier plate by a fixing mechanism, the processing module is operated to perform the first purging process, and, when the front door of the delivering container is connected to the movable door of the load port, the first purging process stops.

13. The method as claimed in claim 11, wherein, in the main purging step, when the front door of the delivering container is moved downwardly with the movable door, the processing module is operated to perform a selected one of the first purging process and the second purging process, and, when the front door is moved upwardly with the movable door, the selected one of the first purging process and the second purging process stops.

14. The method as claimed in claim 12, wherein, in the final purging step, when the front door is disconnected from the movable door, the processing module is operated to perform the second purging process, and, when the fixing mechanism is operated to release the delivering container from the carrier plate, the second purging process stops.
